(19) United States
(12) Patent Application Publication
(10) Pub. No.: US 2004/0099887 A1
(43) Pub. Date: May 27, 2004

(54) Engine that captures additional power from wasted energy

(76) Inventor: Lloyd R. Hazelton, Green Valley, AZ (US)

Correspondence Address: LLOYD HAZELTON, 991 CAMINO DEL DESIERTO, GREEN VALLEY, AZ, 85614, US

(21) Appl. No.: 10/364,901

(22) Filed: Feb. 11, 2003

Related U.S. Application Data
(63) Continuation-in-part of application No. 10/016,098, filed on Oct. 31, 2001, now abandoned.

(51) Int. Cl. H01L 27/148

(52) U.S. Cl. 257/232

(57) ABSTRACT

This invention relates to improving the internal combustion in reciprocating engines of 4 or 2 cycle operation, and more particularly to reciprocating engines which are compounded in order to provide extension of the expansion event. Both primary cylinders and larger secondary cylinders have pistons moving in block cylinders that are cooled and lubricated as usual, but added cylinders are fastened on the top of each block cylinder, each of the same bore and axially aligned with the block cylinder below them, their length that of the stroke of their piston. At the top of each piston's stroke, the piston is in the block cylinder as usual with rings in the normal place, but above the block, the piston extends toward the head, slightly smaller, and concentric with the lower part, a distance for the right compression ratio. This space between the piston and cylinder allows both to operate at high temperatures, but not touch each other, so no lubrication is needed. Each primary cylinder, with its piston and the head, form a space where compression, combustion and expansion occur. The added cylinder and upper end of its piston are not cooled and operate perhaps red hot, and both can stand high temperatures. The secondary cylinder and piston are made the same way, so they operate hot, but no fuel is added. This allows combustion to occur in both cylinders with very limited loss of heat and near complete expansion of the working fluid, for more power with the same amount of fuel, and less pollution.

### CROSS-REFERANCE TO RELATED APPLICATIONS

Not applicable

### FEDERALLY SPONSORED RESEARCH

Not applicable

### SEQUENCE LISTING OR PROGRAM

Not applicable

### BACKGROUND OF THE INVENTION

This invention relates to heat engines, specifically to engines that run at extra high temperatures.

### DESCRIPTION OF PROIR ART

Internal combustion engines on the market today have cylinders in which combustion occurs driving pistons to do work. In general there's a head fastened to the block on the opposite end as the crankshaft. The pistons, driven by the crankshaft, slide in the cylinders forming a seal. In this space within the cylinder, enclosed by the head and the piston, the combustion occurs. In order for the piston to slide, it needs lubrication. To prevent the oil from burning up, the cylinder walls must be cooled. The cooling however reduces pressure and so also the power of the engine.

Various means have bean tried to make engines where the combustion chamber is not cooled, using such materials as ceramics and other high temperature materials, and lubricants. I've seen none on the market. And I understand none were successful.

The combustion in the cylinder causes a high temperature in the air-fuel mix. If there were no increase in temperature there would be essentially no increase in pressure. The cooled cylinder walls drastically cools the air fuel mix thus lowering the pressure and the power output. There's about as much energy lost by cooling this mix as is turned into useful power by the engine.

U.S. Pat. No. 3,808,818 to Cataldo (May 7, 1974) shows engines, all with cylinders having compression modes, primary expanders and secondary expanders. In the expanders combustion takes place in a cooled cylinder or chamber.

U.S. Pat. No. 4,663,938 to Colgate (May 12, 1987) shows various compressors and engines. All have a system to control the working fluid flow into the cylinders or working spaces to produce near laminar flow. This is to keep the working fluid spinning in the cylinder to try to keep the colder part on the outside, with the hotter on the inside. This is an effort to minimize the loss of heat to the cylinder walls by convection from turbulent air flow. In all cases combustion occurs in cooled spaces.

There are three ways to transfer heat: conduction, convection, and radiation. Air has a conduction rate of 0.000057 compared to a rate of 0.115 in steel under the same system of measurement.

Convection is movement of air or other fluid to carry the heat to another place. This is the system that Colgate is talking about. There is a boundary layer on the walls of cylinders and other parts that is subject to the very low rate of conduction of air. In convection the working fluid has to get close to the walls to transfer its heat. In an engine there is a very short time for that transfer.

Radiation transfers it energy at the speed of light. Every burning particle radiates its energy in all directions. It is unhindered by boundary layers or movement of the particles close to a surface. Where the transfer from convection is proportional to the difference in temperature, the transfer due to radiation is proportional to the 4^{th} power of the absolute temperature. Combustion occurs at very high temperatures.

For these reasons I believe radiation must play a very important part in heat transfer in engines. From this, the results of the above patent may not be as expected.

This engine shows cooling passages in its block which drain away energy that could make power.

U.S. Pat. No. 4,159,700 to McCrum (July 3, 1979) shows various overlapping in the strokes of cylinders that work together. I believe it is most efficient to have cylinders that work together as expanders to be set 180 deg. apart. In other words they each travel in opposite directions. This allows the primary firing cylinder and piston to get the full power from its own combustion. Then it exhausts into a much larger cylinder, which gets a full power stroke from the exhaust. McCrum's engine also, from its construction, must have cooled cylinder walls in both the primary and secondary expanders.

U.S. Pat. No. 5,072,589 to Schmitz (Dec. 17, 1991) shows engines with primary and secondary cylinders with pistons, in which combustion occurs, and from this fact their cylinder walls must be cooled.

U.S. Pat. No. 5,325,824 to Wishart (Jul. 5, 1994) shows a primary piston and cylinder exhausting into a secondary larger piston and cylinder. Like all the previous patents, the walls of the cylinders must be cooled, which is shown in the drawing. Cooling the walls not only wastes energy that should be available, but the cool walls are certain to contribute to unburned fuel. Even today new cars have catalytic converters to burn fuel the engine didn't make use of.

All the internal combustion engines heretofore known have a number of disadvantages:

(a) The best efficiency of diesel engines and turbines is 38-40%, auto gas engines are around 30%. This means that 60 to 70% of what we pay for is lost.

(b) This extra use of fuel also makes more pollutants such as hydrocarbons, CO₂, CO, and Nitrogen compounds.

(c) Fuel burned in cooled cylinders doubtless produces more hydrocarbons also.

(d) Considering the enormous amount of oil we burn every day, even a small improvement would be a real help. Any oil we don't use today will help in the future.

(e) Any reduction in oil shipped into our country, or anywhere else, will have an equal chance to reduce oil spills.

(f) If we reduce oil use we can keep more of our oil in reserve for an emergency.

(g) The pressure on our wilderness areas will be reduced.

### OBJECTS AND ADVANTAGES

Accordingly, several objects and advantages of the my invention are:

(a) To provide an engine unit whose hot, insulated cylinder walls reflect the heat, whether from conduction, convection, or radiation, back into the working fluid to produce more power.

(b) To provide an engine unit that is largely made as present engines, with cooling and lubrication and other needs. Certain additions and changes are made. These allows the combustion and expansion to occur in a separate cylinder(s), with piston(s) and head, forming a space that is not cooled except when the temperature is too high for the material used. It is allowed to operate at high temperatures. The lower part of the piston slides in the block cylinder as usual, with lubrication, rings for sealing and cooling, but the top toward the head is elongated, and reaches into a cylinder that is not cooled. It delivers power to the crank shaft, and is controlled by it. Insulation surrounds the cylinder. This cylinder and piston are called the fire cylinder and the fire piston respectively.

(c) To provide an engine unit with a larger cylinder in the block with all the needed parts to operate. This cylinder also has additions and changes which allows for a cylinder with piston to operate as above. It is not cooled except when over heated. This cylinder can receive the combustion products from the fire cylinder(s) or from another engine. This larger cylinder allows further expansion, producing more power with no addition of fuel. It receives more pressure from the fire cylinder(s) than it would from cooled cylinder(s). It also is not cooled where the expansion occurs so that the pressure is turned into work and not lost to cooling. This cylinder is of a size to allow full expansion of the working fluid to maximize power output. This piston is also connected to the crankshaft, and the cylinder is also surrounded with insulation.

(d) To provide an engine unit that has the advantages and improvements that have been developed over the last 100 years and longer. These are combined with the improvements mentioned above. This gives an engine with good power, reliability, long life and with the present improvements much better economy. It also gives less pollution. A truck with this engine would be likely to get instead of 7 miles to the gallon, 11 miles to the gallon. At $1.50 per gallon the cost would change from 21.4 cents per mile to 13.6 cents, a saving of 7.8 cents.

In 500,000 miles that would be a saving of $39,000. Multiply this by the number of trucks on the road, and this would make a major difference in our nations balance of payments.

(e) The same is true of automobiles. Although the savings are not as dramatic for each car, there are a lot more cars, and the ratio of saving would be even larger.

(f) Large engines are more efficient than small engines. This is doubtless because if a container such as a cube, is tripled in size, its surface is 9 times as large but its volume is 27 times as large. This shows that in an engine the combusting charge in a large engine is both further from the walls, and has a smaller comparative area to loose heat. In my engine however, the walls are not cooled, so a large engine, such as one for a truck, gets a lot more power from the combustion. My engine when made smaller for a car, would also have hot walls and so its efficiency would approach that of the large one. Both cars and trucks would gain from this added advantage since in the very large ones, is where the best efficiency occurs, such as locomotives.

(g) There are all the other engines in use that this would improve: boats, small air planes, and so forth.

(h) To provide a 4 cycle engine unit.

(i) To provide a 2 cycle engine unit of my design.

(j) To provide a practical engine unit. This engine unit operates very much like the engines in common use today. The compression, combustion, valve operation and all other aspects are essentially the same. The main difference is the combustion is not cooled, in both the fire cylinder, where first expansion occurs and the upper large cylinder where further expansion occurs

The idea above for combustion in hot cylinders uses the proven idea that in an enclosed space the gas inside, if heated, will increase in pressure proportional to the absolute temperature. Its also well known that a lot of heat is given off by an engine's radiator. Just stand near an engine when its pulling a load and you'll feel the enormous amount of hot air coming out. This is also true of air cooled engines. This heat comes from cooling the cylinder walls, thus lowering the pressure inside.

(k) The idea of using larger cylinders to further expand the working fluid from smaller ones to get more power from the same fuel was proven in the triple and quadruple expansion steam engines. It was found that although the cost was greater, the added power received was well worth it. From the information I've received the increase in output was up to 2½ times as great. Those steam engines used triple and quadruple expansion because the steam was saturated. That is, if it expanded very much it condensed into water. This water in the cylinder, if it accumulated, would fill the space as the piston moved toward the head, and if the piston moved further it would break the engine. With multiple expansion cylinders this problem was solved. In my engine all the secondary expansion can take place in one cylinder, as condensation is not a problem.

(l) To provide an engine made of one or more of the units

(m) To provide an engine as in (i) to run on external combustion which would only need a change in the timing of the valves, and an air compressor as part of the engine, thus allowing both cylinders to be expanders with no internal heat supplied. This would be valuable in third world countries where gas or diesel is very expensive compared to average wages. Farm residue, and waste wood, and other available fuel could pump water, grind flour, and do other duties.

(n) To provide an engine as in (j) to be driven by solar energy. With the hot cylinder spaces, and compressed air heated by focused sun light, the combination would very likely be cost effective.

(O) To provide this present engine with a hybrid electric drive to also gain from that combination.

(p) My engine burns the fuel in the fire cylinder, and exhausts it into the large cylinder, where it has time to burn further. During that time it goes past the valve, through the passage way and into the large cylinder. The exhaust going past these causes additional mixing of the working fluid. This is important because there is more time for the fuel to completely burn. The mixing allows the fuel and oxygen to combine more thoroughly. Consequently the fuel burns more completely. This keeps more of the hydrocarbons from being emitted, as well as being a source of more power.

(q) Another advantage is since the radiator for the block is small, with a very low amount of heat to dissipate, the fan is also small, and runs a small part of the time. Large fans take a lot of power.

(r) When a conventional engine runs, driving a heavy load, the exhaust manifold is red hot. (This manifold collects the exhaust from each exhaust valve and directs it into the exhaust pipe). If this manifold is taken off, the noise is like a machine gun, much louder than any motorcycle. If it isn't bright sun light, one sees fire blowing out from each valve perhaps six inches. Each fires in turn, very rapidly so it looks like a sheet of flame pouring out of the side of the engine. The fire is red in color, which means that the carbon particles are still burning. This is where a lot of power is wasted, in pressure, heat, and unburned fuel. In my engine a lot of this lost energy would be made into useful power

(s) The new novel features from above that differ from the prior art, including the listed patents, comprise:

(t) The fire cylinder operates in an entirely different manner than the cooled cylinders of conventional engines or the listed patents above, since its high temperature reflects heat back into the working fluid and is placed in a new position than is on op pf the block toward the head, and is made of high temperature resisting material.

(u) The fire piston is also different in that it is elongated, and made smaller on the end that reaches up into the fire cylinder toward the head and its other end toward the crankshaft is made of a size to fit snugly and slidingly in the block cylinder where it is cooled, lubricated, has rings for sealing and it guides the upper slightly smaller end so it doesn't touch the fire cylinder, and is made of fire resistant material.

(v) The combination of these two allows combustion in a hot cylinder which has known advantages in being more efficient. The insulation around the fire cylinder also contributes a positive advantage to this combination.

(w) The large piston and the upper large cylinder are made like the fire cylinder and the fire piston, only larger, and they have the new novel advantages of the later.

(x) The insulation between the fire cylinder and the head allows a limited amount of heat flow between the two, so the cooling medium that cools the block has minimal heating, and only a small fan is needed to cool it. This saves power, since a big fan takes a lot of power. Some large engine fans take as much as 25 horsepower.

(y) The real difference between my engine and all the others is that they all of necessity have cooled walls where the combustion occurs. This is needed because an engine operated without cooled walls soon gets so hot that the lubrication burns off the cylinder walls and the piston seizes in the cylinder. In my engine the block cylinder walls are cooled as usual so the lubrication works as in a conventional engine, but the fire cylinder, the fire piston, and the head are above the block and form an isolated chamber that needs no lubrication. The unique feature of the piston made smaller where it moves in the fire cylinder allows it to operate red hot and still not touch the fire cylinder and therefore not need lubrication. This allows combustion in a chamber that is extremely hot.

(z) Engines have been around for over 100 years, and there have been attempts to get a design that would allow combustion to occur in hot cylinders, but none were successful. My design above does solve this problem, and I submit that these ideas are both novel and unobvious, since if it weren't figured out in 100 years it doesn't seem it was obvious.

Further objects and advantages are to provide automobile, truck, and other engines which might be as high as 60% efficient, or more. This will leave extra money in almost everyone's pocket. There are so many ways engines are used that the effects of this engine will be wide spread. Still further objects and advantages will become apparent from a consideration of the ensuing description and drawings.

This engine can be a:

(a) diesel internal combustion engine or

(b) a gasoline, propane, natural gas, alcohol, hydrogen or other fuel type internal combustion engine or

(c) a modified two cycle internal combustion engine of my design, using any of these fuels, or my engine used as

(d) an external combustion engine, which would benefit from the efficiency of hot walls of the expansion chamber and with an exceptionally good heat exchanger could be quite efficient or

(e) A solar powered engine as above with these hot expansion chamber walls is likely efficient enough to be cost effective.

The sun delivers energy to the earth's surface at the rate of approximately 2830 KW per acre on a sunny day. This is 1,811,200 KW or 2,440,970 horsepower per square mile. Its 3,814 horsepower per acre. That's a lot of power for a square 209 feet on each side. By using cooled compressed air, instead of boiling water into steam, and then using my engine to get power from full expansion, without loss by cooling, I believe solar power could be cost effective.

### SUMMARY

An internal combustion compound reciprocating engine of conventional design of either 2 or 4 cycle which has a method for combustion to occur in added cylinders and pistons that are not cooled and operate at high temperatures, for greater efficiency.

### KEY TO FIGURES AND NUMBERS

FIG. 1 Sectional view of 4 cycle engine.

FIG. 2 Sectional view of fuel injector and glow plug.

FIG. 3 Sectional view of 2 cycle engine.

FIG. 4 One method of sealing fire cylinder and upper large cylinder.

FIG. 5A method to keep the fire cylinders and upper large cylinder in line with their respective block cylinders.

FIG. 6 Focusing parabolic mirror to concentrate sun's heat on pipe.

FIG. 7 Fixture to bend parabolic mirror to shape for welding.

### NUMBERING SYSTEM

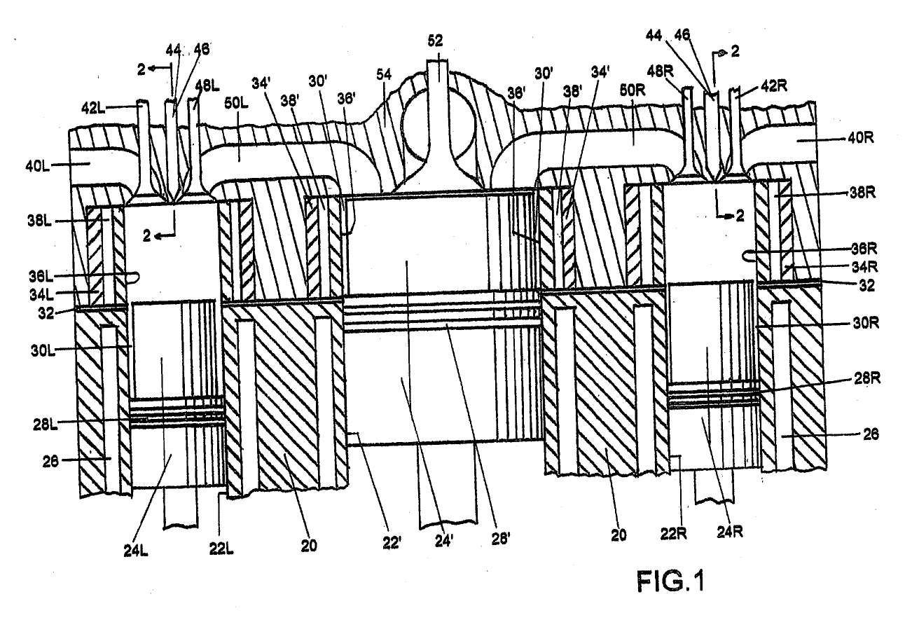

FIG. 1 shows 2 cylinders of the same size and one large block cylinder. Since this figure describes a 4 cycle engine, the two cylinders are identical except that the exhaust valves are each close to the large cylinder. The two identical cylinders are called block cylinders, where combustion and primary expansion take place. For identical parts on these 2, I used the same number with L or R added to show the two sides, When speaking of the two together I showed them thus: 22L&R. On the large block cylinder most all of the parts are the same as on the others. These are numbered as 22′, and so forth.

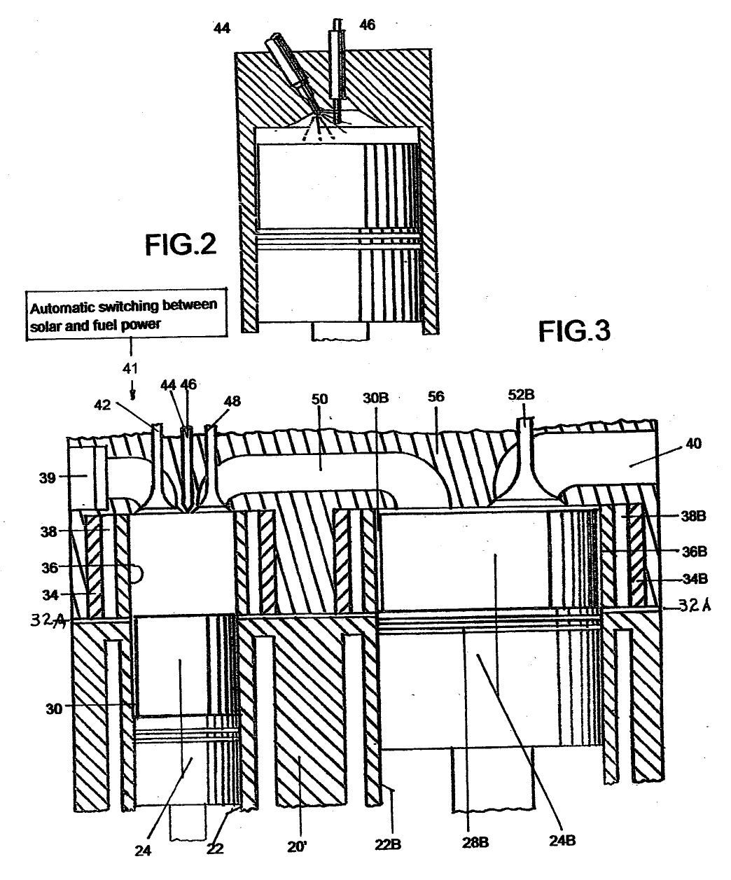

FIG. 3 shows the same engine as a 2 cycle, with 1 block cylinder and one large block cylinder. These are identical in construction as the above. On the block cylinder I have used plain numbers, 22, and so forth. On the large block cylinder I added a B, as 22B, and so forth. Each number by itself then describes the same part in all the cylinders, both in FIGS. 1 and 2.

### REFERENCE NUMBERS IN DRAWINGS

FIG. 1

| | |
|---|---|
| 20 | block |
| 22L&R | block cylinders |
| 22′ | large block cylinder |
| 24L&R | fire pistons |
| 24′ | large piston |
| 26 | cooling passages |
| 28L&R | fire piston rings |
| 28′ | large piston rings |
| 30L&R | space between fire |
| | pistons and fire cylinders |
| 30′ | space between upper |
| | large cylinder and large |
| | piston |
| 32 | insulated gasket |
| 34L&R | insulation around fire |
| | cylinders |
| 34′ | insulation around upper |
| | large cylinder |
| 36L&R | fire cylinders |
| 36′ | upper large cylinder |
| 38L&R | space between fire |
| | cylinders and insulation |
| 38′ | space between upper |
| | large cylinder and |
| | insulation |
| 40L&R | air intake passages |
| 42L&R | intake valves |
| 44L&R | Injector nozzles |
| 46L&R | glow plugs |
| 48L&R | exhaust valves |
| 50L&R | passages from exhaust |
| | valves to upper large |
| | cylinder |
| 52 | large cylinder exhaust |
| | valve |
| 54 | head |

Section 2-2

| | |
|---|---|
| 44 | Injector nozzle used in all fire |
| | cylinders |
| 46 | glow plug used in all fire |
| | cylinders |

2 CYCLE VERSION

| | |
|---|---|
| 20′ | block |
| 22 | block cylinder |
| 22B | large cylinder |
| 24 | fire piston |
| 24B | large piston |
| 30&30B | space between piston and |
| | cylinder walls |
| 34 | insulation around fire cylinder |
| 34B | Insulation around upper large |
| | cylinder |
| 36 | fire cylinder |
| 36B | upper large cylinder |
| 38 | space between fire cylinder and |
| | insulation |
| 38B | space between upper large cylinder |
| | and insulation |
| 39 | air compressor and cooling unit for |
| | intake air |
| 40 | exhaust passage |
| 41 | automatic switching between solar |
| | and fuel power |
| 42 | fire cylinder intake valve |
| 44 | injector nozzle |
| 46 | glow plug |
| 48 | fire cylinder exhaust valve |
| 50 | exhaust passage going to large |
| | cylinder |
| 52B | exhaust valve for large cylinder |
| 56 | head |

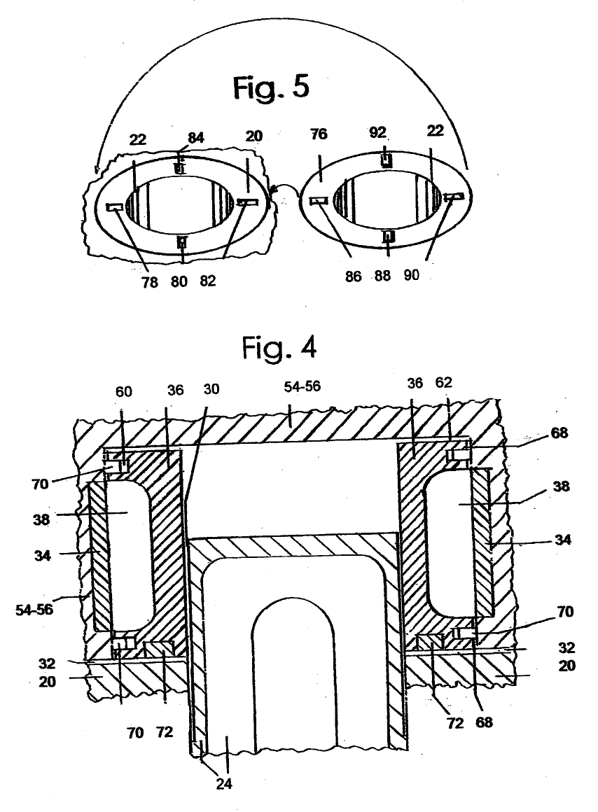

FIG. 4

| | |
|---|---|
| 20 | Block |
| 24 | piston |
| 30 | space between fire piston and |
| | fire cylinder |
| 32 | insulating gasket |
| 34 | fire cylinder insulation |
| 36 | fire cylinder |
| 38 | space for cooling |
| 54 or 56 | cylinder head for either 4 cycle, |
| | or 2cycle engine |
| 60 | space behind cylinder sealing |
| | ring |
| 62 | space for expansion of fire |
| | cylinder axially |
| 68 | space for expansion of fire |
| | cylinder radially |
| 70 | fire cylinder sealing ring |
| 72 | insulation between fire cylinder |
| | and head |

FIG. 5

| | |
|---|---|
| 20 | blocks |
| 22 | cylinder bores |
| 76 | fire or upper large cylinders |
| 78 to 84 | keysways on blocks 20 and 20A |
| | surrounding cylinders |
| 86 to 92 | keyways with keys in them on bottoms |
| | if fire cylinders and upper large cylinders |

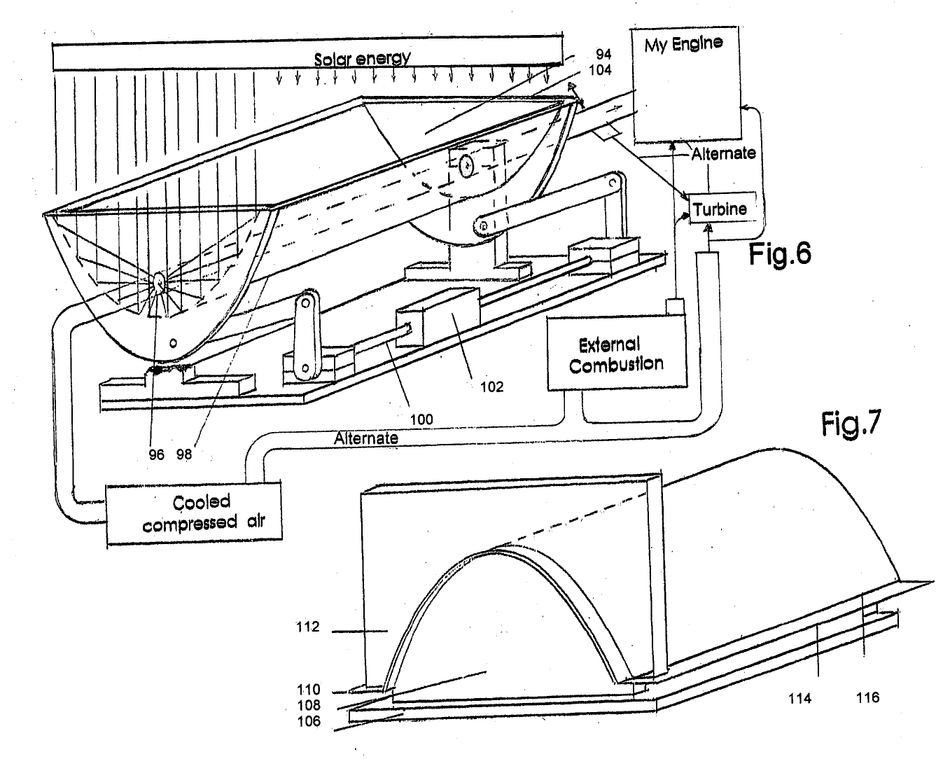

FIG. 6

| | |
|---|---|
| 94 | transparent top |
| 96 | pipe heated by sun and axis for |
| | parabolic collector |
| 98 | parabolic shaped collector |
| 100 | shaft with levers and connecting |
| | bars to focus collector |
| 102 | drive for focusing |
| 104 | end plate, one for each end |

FIG. 7

| | |
|---|---|
| 106 | base of bending fixture |
| 108 | lower bending die |
| 110 and 114 | edges of sheet metal bent |
| | by dies |
| 112 | upper bending die |
| 116 | bend on each side for flange |
| | that strengthens sides |

### DETAILED DESCRIPTION

### Numbering System, Repeated

FIG. 1 shows 2 equal sized cylinders called fire cylinders, and 1 large cylinder. Since this figure describes a 4 cycle engine, the fire cylinders are identical except that the exhaust valves are each close to the larger cylinder. The fire cylinders are where combustion and primary expansion take place. For identical parts on these 2, 1 used the same number with L or R added to show the two sides, When speaking of the two together I showed them thus: 22L&R. On the large cylinder most all of the parts are the same as on the fire cylinder. These are numbered as 22′, and so forth.

FIG. 3 shows the same engine as a 2 cycle, with 1 fire cylinder. The fire cylinder and large cylinder are identical in construction as the above. On the fire cylinder I have used plain numbers, 22, and so forth. On the large cylinder I added a B, as 22B, and so forth. Each number by itself then describes the same part in all the cylinders, in both FIGS. 1 and 3.

### Detailed Description

Description—FIG. 1 Preferred Embodiment

A preferred embodiment is shown in FIG. 1 This shows a sectional view of an engine block with 3 cylinders that work together as a unit. As many of these units as needed can be incorporated in one engine. In the following discussions of the engines, up will be toward the head, and down will be toward the crankshaft.

The engine unit is composed of block 20 which contains block cylinders 22L&R and a large cylinder 22′. Except for the differences in the cylinders sizes, this block is conventional. This block also is fitted with a crankshaft, and connecting rods. These connect the crankshaft to the pistons 24L&R and 24′ with bearings on each end of all the connecting rods, (not shown). The block has other parts needed for operation, such as a lubrication system, cooling system, electrical system, starter, drive for the camshaft and all other items needed for a conventional engine. (These are not shown.) Coolant 26 is used in the engine block 20 or it could be air cooled.

Between the top of the block and the head is placed an insulating gasket 32. Placed on top of the gasket are fire cylinders 36L&R, and the upper large cylinder 36′. Each one has the same bore as the block cylinder it fits above, and they have the same axial alignment. Their length is essentially that of the stroke of the pistons that slides in them. In block cylinders 22L&R slide fire pistons, or moving walls 24L&R. The fire pistons and large piston are made like a conventional piston with rings 28L&R and 28′, and piston pin (not shown). When these pistons 24L&R are at top dead center the rings are still in the top end of the block cylinder walls as usual. In this position the pistons continues full size to the tops of the block cylinders 22L&R. From this point, upward toward the head 54 the fire pistons 24L&R are elongated and have a smaller diameter. The length of this elongation is the same as the stroke of the piston except possible small variations to control the compression ratio. The same is true of the large piston 24′ except it only needs clearance from the head. These pistons, fire cylinders and upper large cylinders are made of material that has adequate strength at high temperatures. They are expected to operate red hot or higher, depending on the material they're made of. The fire cylinders 36L&R surround the upper end of the fire pistons 24L&R when they're at the top of their stroke. The same is true of the upper large cylinder 36′ and the large piston 24′. The smaller diameter of the top of the fire and large pistons makes a space 30L&R and 30′ between them. This prevents the piston's hot surfaces, (red hot), from touching the hot fire cylinder walls 36L&R, or the upper large cylinders walls, which could cause galling and seizure.

This is one of the most important features of this design. The clearance needs only be large enough to compensate for expansion and contraction of the pistons and cylinders, and warpage caused by uneven heating and cooling. Its purpose is to allow the pistons to run freely without touching and without lubrication. The lower part of the pistons runs in the cooled block cylinder. This provides four things: Sealing for the high pressure, lubrication between the piston and the block cylinder, guidance for the top of the fire piston so it doesn't touch, and cooling so the lubrication isn't burned up.

This arrangement allows combustion to take place in the fire cylinders 36L&R, enclosed by the fire pistons 24L&R and the head 54. Therefore the combustion takes place in an isolated space, not cooled, and with the hot fire pistons 24L&R not touching the hot fire cylinders 36L&R so no lubrication is needed there. The lower part of the fire pistons 24L&R operate in the cooled block cylinders 22L&R so they have lubrication, and provide guidance to the upper hot end of the piston.

Surrounding the fire cylinders 36L&R is a space 38L&R. This is true also of the upper large cylinder 36′ and the space 38′. This allows cooling if the temperature gets too high for the material the cylinders are made of. Outside of this space, there is insulation 34L&R and 34′ to preserve heat, so cylinders 36L&R and 36′ operate as hot as possible within their limits.

If a material, or a combination of materials is used to construct the fire cylinders, 36L&R and upper large cylinders 36′ is made so it has insulation properties good enough to operate without the need for insulation 34L&R and 34′ and/or cooling space 38L&R and 38′, this is equivalent to having fire cylinders and upper large cylinders with cooling spaces and/or insulation as above. This is also true with fire cylinders 36 and upper large cylinders 36B.

Passages 40L&R are for intake of air that passes through valves 42L&R.

FIG. 2 shows an injector 44 and a glow plug 46. These are placed near valves 42L&R and valves 48L&R in cylinder head 54. These are also shown in FIG. 3. The head also has cams, and rocker arms and so forth. (not shown). Passages 50L&R allow exhaust gases to pass through exhaust valves 48L&R and into the upper large cylinder 36′. In cylinder head 54 above the upper large cylinder 36′ is exhaust valve 52.

Cylinder head 54 surrounds the two fire cylinders 36L&R and the upper large cylinder 36′, and their insulation 34L&R and 34′. It also seals the fire cylinders and the upper large cylinder from leaking pressure, and allows for expansion and contraction of cylinders 36L&R and 36′.

FIG. 2 shows an enlargement of injectors nozzles 44, and glow plugs 46. These are used with all fire cylinders to supply fuel, and when the engine is cold, the glow plugs help start it. These are placed near valves 42L&R and valves 48L&R in cylinder head 54. These are also shown in FIG. 3.

The following describes a conventional engine that my invention is based on, and is followed by the improvements that are part of my invention.

This engine is an internal combustion compound reciprocating engine of the type operating as a four cycle engine, and including but not limited to the following:

primary cylinders and secondary cylinders arranged in groups of three with two primary cylinders of equal size and a larger secondary cylinder forming a group, preferably with the secondary cylinder between the primary cylinders, as many of these groups can be incorporated in one engine as desired,

the primary cylinders being distinguished from the secondary cylinder as serving as prime movers in a conventional manner, and initiating a combustion phase of the engines operating cycle as an expansion event the cylinders which are cooled as is conventional;

and including a reciprocal piston in each cylinder, a crankshaft, and connecting rods conventionally connecting the respective pistons to the crankshaft for converting the effects of fuel combustion into propulsive mechanical force as engine output;

a method for supplying primary air and fuel only to the primary cylinders, and in quantities for the most efficient use, and pollution control;

a method for timely igniting the air and fuel to effect engine working fluid;

and including a head, and its intake and exhaust ports and their respective valves in the primary cylinders, and in the secondary cylinder; an exhaust port and its valve;

gas transfer conduits, each compounding the primary cylinders and the adjacent secondary cylinder, and particularly connecting the exhaust ports of each primary cylinder to a valveless port at and forming part of the combustion chamber of the secondary cylinder, whereby one of the primary cylinders exhausts to the secondary cylinder on one revolution, and the other primary cylinder exhausts to the secondary cylinder on the next revolution, together providing a power stroke for the secondary cylinder on every revolution, in a manner so each primary cylinder has a complete expansion cycle before exhausting into the secondary cylinder, and when that exhausting begins, the secondary piston is at or near the top of its stroke, so it can have a complete cycle of expansion on each revolution without overlapping of their power strokes;

a method for opening and closing the valves in accordance with the timing required by

the engine's operating cycle and regulated by the crankshaft;

the cranks having crankpins disposed such that there is effected equal spacing of primary cylinder expansion events, equally spaced secondary cylinder expansion events, and the primary pistons in each group of three moving up and down together in a known manner, and the third, the secondary piston, always moving in the opposite direction as the primary pistons;

an exhaust system for transferring the engines final exhaust from the secondary cylinders to the atmosphere;

wherein, the improvement comprises:

added cylinders, of both primary type, called fire cylinders and secondary type called upper large cylinders, the fire cylinders are placed on top of each block cylinder, extending toward the head, and of the same bore as the block cylinder below it and axially aligned with it and whose length is essentially the same as the stroke of the piston that moves in it;

fire pistons slide in the block cylinders and are made as conventional pistons, with rings to seal the pressure from the combustion, and when each fire piston is at its top dead center, its top reaches to the top of the block cylinder as usual, with the rings still in the block cylinder, but above the top of the block, the piston continues up with a slightly smaller diameter, coaxial with its lower part, reaching up into the fire cylinder until its top is the right distance from the head to have the right compression ratio;

the upper large cylinder is placed above the large block cylinder in the same manner as the fire cylinders, the large piston moving in the large block cylinder, with the same design as the fire piston and moves close enough to the head for a small amount of clearance, so they don't touch, its lower part sliding in the large block cylinder in a conventional manner, and including rings for sealing, with its upper part made smaller as in the fire cylinder;

the space between the fire cylinder and the fire piston made by the smaller diameter of the top of the fire piston is only enough to prevent the two from touching each other in operation, the same is true of the space between the upper large cylinder and the large piston, and the cylinders and pistons of both types are made of material that can operate at high temperatures with adequate strength, the cylinders are cooled only if their temperature gets higher than the safe operating temperature of the material they are made from;

whereby: the combustion and expansion takes place in a chamber surrounded by the fire cylinder, the fire piston and the head, the chamber not cooled, and its high temperature produces high pressures and it is isolated from the cooled block cylinder, which provides cooling, lubrication, sealing of pressure of the working fluid and guidance of the upper part of the fire piston;

and with the secondary expansion performed in the same manner in the upper large cylinder and the large piston and the head, it also operates hot, so the higher pressures in both the fire cylinders and the upper large cylinders, made from the high temperatures, produce more power for the amount of fuel consumed, and since no extra fuel is used in the upper large cylinder the combination makes a very efficient engine.

These engines can also include the following:

a supper charger to supply more air for greater power output, a cooling space and insulation around all the fire and the upper large cylinders, and an insulating gasket between the block and the head, to minimize the heat flow from the fire and upper large cylinders to the cooled block, therefore needing only a small fan for cooling, thus saving power,

a material, or a combination of materials used to construct the fire cylinders, made so it has insulation properties good enough for operation without the need for insulation and/or cooling spaces around the cylinders, can replace the latter, and this also includes the upper large cylinders;

the secondary cylinders instead of being one cylinder in each group of three, are multiple cylinders receiving the exhaust jointly and working together for its further expansion, the secondary cylinders may also have different strokes than the primary cylinders.

In the operation of the internal combustion engines, air enters through intake valves, into the fire cylinders, is compressed, fuel is injected, and combustion takes place:

a. driving the fire pistons downward, and the high temperature, and high pressure of burning the working fluid encounters hot insulated fire cylinder walls and the fire pistons that are not cooled, and being very hot, they reflect the heat back into the working fluid to retain its heat, and thereby its pressure, and only losing heat by the work it is doing by expanding, driving the piston down;

b. thus delivering considerably more power for the same fuel input, and with hot the chamber walls there is less hydrocarbons emitted, and approaching the bottom of the fire piston's stroke, the exhaust valve opens, allowing the working fluid to exhaust and enter the upper large cylinder, which also operates hot, whose piston is now at the top of its stroke; and with less fuel used, less pollution will be generated;

c. and as the fire piston moves up, it pushes the working fluid through the exhaust valve, and the passage, and into the upper large cylinder thus mixing it more thoroughly, and allowing the unburned fuel that's left, to have a longer time to burn and;

d. the mixing allows the burning particles to find more oxygen for more complete burning, and the moving of the large piston downward with the pressure on its much larger cross sectional area causes a great deal of force on the crankshaft even though the pressure is falling;

e. and in operation, the temperature of the fire or upper large cylinders in any of these engines is expected to be up to red hot or higher, the working fluid is not cooled, as in a conventional engine with some of its energy and pressure lost to the radiator, but it retains essentially all of its pressure to expand and drive the piston down delivering more useful work with no more fuel;

f. the savings of fuel from the hot the fire cylinder, and the fire piston, combined with the free power from the upper large cylinder and large piston makes a very efficient engine, which by using less fuel less pollution, and with large numbers of these engines in cars and trucks and other uses a great deal of fuel can be saved, as well as reducing pollution, and since this engine operates as conventional engines, except for certain additions and modifications, its reliability will be high;

g. and these engines with of external combustion, will be useful in areas of high fuel costs and low wages and with waste biomass or other fuel used to make power, could be used for pumping water for irrigation, grinding grain, and other labor intensive tasks and;

h. with of solar power, combined with my engine, which allows the complete expansion in hot cylinders, and having of switching to fuel power automatically in the same engine, if the sun fails; in a partly cloudy day the switch from solar to fuel driven power could alternate back and forth as needed, and capture the available sun energy, and still supply a constant energy source, thereby saving fuel, and this is expected to be cost effective, and the manufacture of any of these engines is like any internal combustion engine with some added parts, and modifications so its development will not be difficult.

### Operation FIG. 1

This engine operates as a 4 cycle. A 4 cycle engine cylinder fires on every other revolution. Normally in those engines 2 pistons move to the top together. One fires on one revolution, and the other fires on the next. This is the way my engine works. FIG. 1 shows fire cylinders 24L&R at each end, and the large cylinder 24′ between them. The fire pistons are at the bottom of their stroke, and the large piston at the top. The left fire piston has just completed its fire stroke, delivering power to the crankshaft. The right one has just completed drawing air into the cylinder. This flowed through passage 40R, and past valve 42R, which was open. Since the large cylinder can accept exhaust on every revolution, it takes 2 fire cylinders to supply the large cylinder. In the position shown valve 48L starts to open and allows the exhaust to flow into the large cylinder. There is considerable pressure still in this fire cylinder, which is usually exhausted into the air and wasted. Instead, in my engine, it is directed into the large cylinder, and immediately that pressure is transferred to the large cylinder. The area of this large cylinder is about 5 times (this can vary widely) that of the fire cylinder. Since, in a closed chamber, any pressure on the inside has the same force on every square inch of the surface, the large cylinder will have about 5 times the force downward as the fire cylinder. So, if there were still 100 pounds per square inch at the bottom of the stroke, there would be 5 times more force on the large piston 24′, than on the fire piston 24L. 10 square inches would be a reasonable size for the fire piston. Then the large one would have 50 square inches. Therefore, the force pushing down on the fire piston is 1000 pounds when it is moving up but on the large piston it is 10,000 pounds when it is moving down at the same time. The differences in the forces, 9000, pounds is the net force delivered to the crankshaft. As these continue to move, the fire piston up, and the large cylinder down, the fire piston forces the exhaust gases into the large piston, allowing the large piston to deliver power to the crankshaft that is all free

While the left fire piston 24L is moving up as just described, the right one 24R is doing the same. It has just drawn in air and now it compresses it till it reaches the top of its stroke. At that instant, approximately, fuel is pumped by the injector pump, through pipes (not shown) and the injector nozzle 44R, and sprays into the fire cylinder 36R. Combustion takes place, and with explosive rapidity, the pressure and temperature shoot upward. If the engine is just being started, the glow plug 46R would have been on, and heated red hot to ensure firing.

At this point, my engine is different than conventional engines, In my engine the combustion is taking place in a space surrounded by the fire cylinder, the fire piston, and the head. These are made of materials that can operate at high temperatures. Since this space is not cooled, except if the temperature gets too high for the materials involved, it gets very hot. In a closed space like this the pressure is dependant on the temperature. As the surroundings are hot, the temperature decreases slowly, except that when a gas expands it naturally cools. This cooling is a transfer of heat energy to energy that does the work to push the piston down. The upper large cylinder and the large piston are made similar to the fire cylinders so they also can operate hot. The large cylinder's expanding working fluid is not cooled by cold walls, so it to retains the heat in it, keeping the pressure high. Then the pressure does work driving the piston down.

The combustion has occurred in fire cylinder 36R, and is pushing fire piston 24R downward, producing power. During this power stroke, fire piston 24L is also moving down. It is drawing in more air to compress as it moves upward again. As these two 24L&R move down, the large piston 24′ is moving up exhausting its low pressure through valve 52 This completes one cycle, which repeats over and over. First one fire cylinder fires, delivering power, on its downward stroke, and on its upward stroke it pushes the exhaust into the upper large cylinder where it continues expanding and delivering more power which is free. Then both fire cylinders arrive at the top and the opposite one is ready to fire. At the same time exhaust valve 52 opens and the large piston moves up, pushing the burned working fluid out the exhaust. Insulation 34L&R and 34′ surround the cylinders to conserve the heat.

Insulation is possibly used on piston tops, head, internal fire cylinder walls, and valves, to conserve more heat and to have less heat in those walls.

Let's imagine we have 2, single cylinder engines. They are identical, except one has its cylinder cooled in the normal manner. The other is built like my engine, fully insulated. Let's run them until they are up to operating temperature. After the last explosion we stop them in mid stroke, part way down. Let's also assume that we have perfect sealing on both and perfect insulation on mine. In the normal engine the pressure trapped in the cylinder will rapidly fall to near zero from the cooling. In my engine the pressure would remain there indefinitely. That's because if there is no leakage and the temperature stays high, the pressure also stays high. This demonstrates how the cooled cylinder loses pressure and power.

This engine could also have a hybrid electric drive for an automobile or truck. This is beneficial because when applying the brakes, or going down hill, that energy, instead of being lost would charge a battery, and be used later.

### Description FIG. 2

FIG. 2 shows an enlargement of injectors nozzles 44 and glow plugs 46. These are used with all fire cylinders to supply fuel, and when the engine is cold, the glow plugs help start it.

### Description FIG. 3

FIG. 3 shows a sectional view of an engine block with 2 cylinders that work together as a 2 cycle unit. As many of these units as needed can be incorporated in one engine. The engine unit is composed of block 20′ which contains block cylinder 22 and a large cylinder 22B. Except for the differences in the cylinders sizes, this block is conventional. This block also is fitted with a crankshaft, and connecting rods. These connect the crankshaft to the pistons 24 and 24B, with bearings on each end of both connecting rods, (not shown). The block has other parts needed for operation, such as a lubrication system, cooling system, electrical system, starter, fuel system, drive for the camshaft and all other items needed for a conventional engine. (These are not shown.)

In block cylinder 22 slides a fire pistons 24 and in the large block cylinder 22B slides the large piston 24B. These pistons could be called moving walls. Coolant is used in the engine block or it could be air cooled. When either one of these pistons 24 or 24B are at top dead center (at alternate times) the rings are still in the top end of the block cylinder walls as usual. In this position the piston continues full size to the tops of the block cylinders 22 or 22B. From this point, upward toward the head 56 the fire piston 24, and the large piston 24B are elongated and have a smaller diameter. The length of this elongation is the same as the stroke of the piston except possible small variations. These pistons are made of material that has adequate strength at high temperatures. They are expected to operate red hot or higher, depending on the material they're made of. On top of the block is placed an insulating gasket 32A. Placed on top of the gasket is a fire cylinder 36, and a upper large cylinder 36B. Each one has the same bore as the block cylinder it fits above, and have the same axial alignment as the one below respectively. Their length is the length of the stroke of the piston. The fire cylinder 36 and the upper large cylinder 36B surround the upper end of the fire piston 24 and the large piston 24B respectively, when they're at the top of their stroke. The smaller diameter of the top of fire and large pistons makes a space 30 and 30B between them and their cylinders 36 and 36B. This prevents the hot piston surfaces, (red hot), from touching the hot fire cylinder walls 36 and 36B, which could cause galling and seizure. This is one of the most important features of this design. The clearance needs only be large enough to compensate for expansion and contraction of the pistons and cylinders, and warpage caused by uneven heating and cooling. Its purpose is to allow the pistons to run freely without touching and without lubrication. The lower part of the pistons, (toward the crankshaft), run in the cooled block cylinders. This provides four things: sealing for the high pressure, lubrication between the piston and the block cylinder, guidance for the top of the fire piston so it doesn't touch, and cooling so the lubrication isn't burned up.

An air compressor unit 39 compresses and cools intake air that passes through intake valve 42.

FIG. 2 shows an enlargement of injector 44 and a glow plug 46. These are placed near valves 42 and valves 48 in cylinder head 56. Passage 50 allows exhaust gases to pass through exhaust valve 48 and into the upper large cylinder 36B. In cylinder head 56 above the upper large cylinder 36B is exhaust valve 52B. Cylinder head 56 surrounds fire cylinder 36 and the upper large cylinder 36B, and their insulation 34 and 34B. It also seals the fire cylinder and the upper large cylinder from leaking pressure, and allows for expansion and contraction of cylinders 36 and 36B, shown in FIGS. 4 and 5. In cylinder head 56 above the upper large cylinder 36B is exhaust valve 52B which exhausts through passage 40.

This arrangement allows combustion to take place in the fire cylinder 36 enclosed by the fire piston 24 and the head 56. Therefore the combustion takes place in an isolated space, not cooled, and with the hot fife piston 24 not touching the hot fire cylinders 36 so no lubrication is needed there. The lower part of the fire piston 24 operates in the cooled block cylinder 22 so they have lubrication, and provide guidance to the upper hot end of the piston.

Surrounding the fire cylinder 36 is a space 38 that allows cooling if the temperature gets too high for the material the cylinder and piston 24 are made of. Outside of this space, there is insulation 34 to preserve heat, so cylinder 36 operates as hot as possible within its limits. The same is true of the upper large cylinder 36B and piston 24B, and space 38B surrounded by insulation 34B. When using solar power in the engine of FIG. 3, a modification for, automatic switching between solar and fuel power in the same engine 41 is used to give steady power when clouds cover the sun.

The above engine operates as a two cycle engine of my design, but other compatible 2 cycle designs can also be used, the fire cylinders with firing and expanding on every revolution, their exhaust being delivered to the upper large cylinders which continue the expansion on every revolution, thus needing only one fire cylinder for each upper large cylinder which exhausts into the atmosphere on every revolution.

This engine can operate with no internal combustion, with the primary cylinder is an expander, delivering its exhaust to the secondary cylinder for full expansion or nearly so, or, alternately to a turbine, wherein heating of the working fluid is accomplished by external combustion, useful where fuel cost is large compared to income and can be used for labor intensive tasks.

It can also be driven by the sun's energy, using a solar collector which followings the sun, made of a parabolicly shaped trough to focus the suns rays on a pipe or its equivalent, to heat compressed cooled air to drive one of these engines, and with a method to connect a plurality of these collectors together they can be made to all follow the sun together, thus deriving energy without use of fuel.

The solar collector can also be made with reflectors located in a field surrounding a tower, the top of the tower having a heat exchanger. The reflectors are controlled so each, continually, reflects the suns rays onto the heat exchanger to heat compressed cooled air to drive one or more of these engines. These controls can be adjusted to not follow the sun when needed. This has the advantage of concentrated sunlight from a large area acting on a small target—the heat exchanger—, so a lot of piping is eliminated, needing only enough to connect the heat exchanger with the compressor and the engine. But it will take a more complex controller to operate the movement of the reflectors. This is already known in prior art, and is not shown.

Both of these solar collectors are already known, but with the combination of cooling air as it is compressed, with its greater efficiency, and with the engines described above with their great efficiency, the combination, I submit are novel.

Both the 4 cycle and the 2 cycle engines can operate on a large variety of fuels including but not limited to:

diesel, gasoline, propane, natural gas, alcohol, hydrogen or other fuel type. These engines can also use a hybrid electric drive for cars and trucks wherein lost energy from braking, and going up and down hills is saved, to be used later.

### Operation FIG. 3

Drawing 3 shows fire piston 24 at the bottom of its stroke and the large piston 24B at the top. The fire piston has just finished its power stroke and the exhaust valve 48 is just starting to open. This allows the still high pressure of the fire cylinder to flow into the upper large cylinder 36B The large cylinder is much larger, perhaps 5 times as much area, more or less. The pressure is nearly the same on each square inch of each piston as one moves up and the other moves down. This that if the large piston has 5 times the area of the other, the force down on its connecting rod is nearly 5 times as great. Even though the pressure in this cylinder gets much less, or goes to zero, by the bottom of the stroke, the piston has utilized the energy of the decreasing pressure. Since its area is much larger, it delivers a lot of force, even at low pressure, to the connecting rod, and also more power which is all free. By the time the large cylinder is one half or five eighths of the way down its stroke the pressure is very low perhaps 20 psi. At the same time the fire piston is one half to three eighths of the way from the top. Then the exhaust valve of the fire cylinder closes. Very shortly afterward, its intake valve opens, allowing the compressed, cooled air to enter from the compressor. It is only opened till the piston gets approximately one quarter of the way from the top. This allows the fire piston to finish compressing the air, in the closed cylinder. Then the fuel is injected the same as in the 4 cycle engine, in a manner so the pressure isn't too much for the engine. If the engine were built stronger, then the fuel could be injected faster, and the temperature would rise faster. This results in greater economy. At this point there is a small residue of exhaust gas left in the fire cylinder. This is from the exhaust valve closing early. This acts as a means of anti-knock. I believe that gasoline or diesel fuel could be handled this way, or other fuel if it was done right. With both valves closed, the fire piston is driven downward delivering power to the crank shaft. As it moves down, the large piston moves up, exhausting the very low pressure in it. This repeats every revolution, so the fire cylinder fires every revolution, and delivers exhaust to the large cylinder every revolution, and this lets the working fluid continue to expand. This provides force to the large piston to make more power every revolution which is all free. Both pistons operate as 2 cycle units, so only one fire cylinder and piston are needed.

FIG. 4

FIG. 4 shows a method that allows the cylinders to expand, and contract, but also remain sealed, and stay inline. It represents both the fire cylinder(s) and the upper large cylinder(s) in either the 4 cycle or the 2 cycle engine. Most of the numbers are shown on

FIG. 1, but some are added. Number 60 is a space behind sealing ring 70. This space could contain a corrugated spring to hold the seal ring spaced equally from the cylinders 36. There are other ways to do this, one of which is shown in FIG. 5. A space 62 allows the cylinder to expand axially. A space 68 allows the cylinder to expand radially. The spring tension of the ring forces it against head 54 or 56 to keep it sealed. A piston 24 moves in any of the cylinders. Insulation 72 is provided to help insulate the cylinder from the block. The Insulating gasket 32 also serves this purpose. The two could be combined. A good material for this is ceramic fiber insulation. It could be used here and in the other places requiring insulation. The low priced variety can stand close to 2500 deg. F. It comes in blanket, board, and paper. These can be found in ceramic supply stores. There are also other grades that stand higher temperatures. The space shuttle uses this type of material to cover its surfaces for re-entry.

Blocks 20 and 20′, space 30L&R, 30′, 30 and 30B, insulation 34, 34B, 34L&R and 34′, Cylinders 36L&R, 36′, 36, and 36B, and space 38, 38B, 38L&R and 38′ shown in FIG.'s 1 and 3 are shown on FIG. 4 as 20, 30, 34, 36 and 38 respectively. FIG. 4 represents a method of sealing, and allowing to expand all of the cylinders in FIGS. 1 and 3 FIG. 5 FIG. 5 on the left side shows the top of any of the block cylinders 22L or 22R or 22′. It also represents either of the top of the block cylinders 22 or 22B. The right side shows the bottom side of any of the fire cylinders, or the upper large cylinders. Numbers 78, 80, 82, and 84, are key ways. Numbers 86,88, 90, and 92, are projections that fit in the key ways of the left side. They fit snugly into each other but are free to slide. The reason for this arrangement is to keep the top and bottom cylinders centered with each other but able to expand and contract. When the cylinders are fit together, the keys and key ways on opposite sides (78 and 82 fit into 86 and 90). To keep the axis of the 2 cylinders centered with the one another in one direction. The same is true of the other set, (at 90 degrees to the first set) so the cylinders do stay in line but any change in size keeps the axis of the top and bottom cylinders centered with each other, so the outside walls move in and out but the center of each stays in line.

The projections 86, 88, 90, and 92 could be made by making key ways, and then using keys to fit between the left and right sides, or the projections could be machined integrally with the cylinders. Number 20 is any of the block cylinders, 22 is the bore of any of the cylinders and 76 is the bottom of any of the fire cylinders or upper large cylinders.

FIG. 6

FIG. 6 shows a solar collector. The suns energy is focused on a pipe 96 by a parabolic reflector 98 and has ends 104. It also has a transparent top 94. The solar parabolic reflector is aimed at, and follows the sun by mechanism 102, which drives the shafti 00 with its levers and connecting bars. This drive keeps both ends of the collector pointing the same way, so it is in focus the full length of the pipe. One drive mechanism can drive an array of collectors by simply connecting rods together to drive them all in unison and pointing the same way. The preferable way to mount the collector is with its axis north to south. This allows the collector to follow the sun all day long with only one motion. If it is mounted flat with the ground the installation is less costly. If it is mounted with one end higher than the other, so the sun strikes it squarely, and it can be a little shorter for the same output. Either way the pipe is kept at the line of focus so all the sun's energy is focused on the pipe. This has been done before, making steam to drive an engine. That method was very inefficient. Approximately 1.5% of the energy that hits the ground was usable. The steam locomotive with single acting cylinders was about 5% efficient. I believe however that using highly compressed air, which is cooled as it is compressed, is much better. This method avoids evaporating water which takes a lot of energy. It is essentially the same as a conventional engine which first compresses the working fluid, then heats it, (the burning of fuel) and gets power from the high pressure.

An important consideration is the compression of the air just mentioned. Any gas follows the law that if it is heated and kept at the same volume, its pressure increases proportional to the absolute temperature. If we heat air at 25 psi to 4 times its absolute temperature, its pressure will increase 4 times if kept at the same volume. When work is gotten from it as the pressure decreases the force on the piston is 25 psi falling toward zero. If however our initial pressure is 1000 psi and using the same size piston and cylinder the pressure falls from 1000 psi toward zero, thus deriving lots more power from the same space. (This example disregards atmospheric pressure).

The large steam power plants operate at about 1000 to 1100 deg. F. If the compressed air is not cooled as it is being compressed, it ends up taking a lot more power. A diesel engine has a compression ratio of about 16:1 If air is compressed at that rate without cooling, starting at 50 deg. C. (122 deg. F.) its temperature rises to 630 deg.C. (1166 deg. F.) Its pressure rises to 650 psi. (These numbers were derived from “Heat and Thermodynamics”, by Mark W. Zemansky, and Richard H. Dittman, 6th edition).

If the temperature is maintained at the initial temperature, (by cooling) and is compressed at 16:1 its pressure increases 16 times its original pressure. At 14.7 psi atmospheric the pressure is 235 psi. Its obvious that it takes a lot more power to rise the pressure from 235 psi to 650 psi. Another way to look at it is that if air is introduced into the pipes at 1166 deg. F. it is already above the operating temperature so no more heat can be added. The only power available is what was put into it less friction and heat losses. If the system is operated at 1000 deg. F high temperature and 180 deg. Low, the absolute temperatures are 810 K, and 355 K. This gives a maximum possible efficiency of 56%. Lets cut that to 40% due to loss in radiation. My engine will be very efficient, I believe 40% or more. Over-all this would be 16%. It likely be greater than that since the engine is only converting pressure into work, and the heat system is already discounted.

In all systems described above, where compressed cooled air is used, one advantage is described above. Another way to look at it to see its advantage is the follows. I calculated one time, if air and fuel such as gasoline are mixed together in the best mixture, when burned together, the temperature would rise by 1371 deg. C (2500 deg F.) The formula for the maximum efficiency for a gas to operate between 2 temperatures is the high temperature, T1 minus the law temperature T2 divided by the high. (T1−T2)/T1

Absolute Temperature is 1644 K

In Direct Use Of The Sun's Energy by Dr. Farrington Daniels, it is stated that on the earth's surface, energy from the sun averages approximately 2830 kw per acre when the sun is shining. At 8 hours per day and 300 sunny days per year this would be=6,792,000 kw hours per year. Multiplied by 16% from above that is 1,086,720 kw hours. At 5 cents per kw hour that is worth $54,335. An acre is just less than a square 209 feet on a side. From the above, this better way of collecting heat from the sun, combined with my engine which allows the working fluid to do work while expanding completely, and in uncooled cylinders, is a system that I believe is economically feasible.

In FIG. 6, note that the Cooled compressed air can travel different routes. It can flow through the solar collector, and to my engine, or alternately to a turbine, preferably one that gets power from the full expansion of the air. Another route is to an external combustion heat exchanger that discharges directly into either my engine or the turbine. This allows use of almost any fuel.

It also requires the timing of the intake valve of my engine to open at the top of the stroke, as in a steam engine. Another route is to go directly from the compressor and cooler to either my engine, or the turbine. This would require fuel, and operate as an internal combustion unit. This allows power to be generated from different sources to fill in when the sun is not adequate, thus giving a steady flow of power, from efficient sources, and also allows use of solar power when its available. (Its also free). When my engine is used along with the solar collector the valve timing will have a method for changing automatically, and while running. While the engine is being driven by the solar collector the valve will have the right timing, but when the sun fails the timing will change automatically, and fuel will be injected.

FIG. 7

FIG. 7 shows one way to make these parabolic collectors. A lower die 108 is fastened to base 106 and is used to form sheet metal into a parabolic shape for the collector. Side edges of the sheet metal 110 and 114 are shown with bend 116 that stiffens the edges. The top die 112 forms the sheet metal over the bottom die 108 so it has an accurate bend. There is a set of these dies at both ends and as many in the center as needed. The dies at the ends are placed a short distance from the ends of the sheet metal to allow room for welding the ends 104 (from FIG. 6) to the parabolic shaped sheet. While the sheet is still held in the dies additional shaped pieces can be fastened to the outside to maintain its shape, if needed.

Imagine a sheet of metal (likely aluminum or steel) about 1/32 inch thick. Its width is enough to bend over the bottom dies and be formed by the top dies, reaching from edges 110 to 114.

This sheet of metal is very long and is rolled into a coil on a spool with supports so it can turn. The end of the sheet is placed between rollers, or other means, which pulls the sheet off the coil, feeding it through an open shear, and measures it to length. The shear cuts it and its fed through a series of rollers that form the bends on each edge 110 and 114. The upper dies are raised so the sheet can be guided accurately over the bottom dies. Then the upper dies come down and form the shape and hold it there. The end plates 104 having been cut out, and with the holes in them are placed and clamped lightly for welding. These need to be placed and held accurately. This can be done with a fixture, automatically, or placed in a fixture by hand. Next it is welded with robot welders, (or by hand). This operation, if using automation for placing the ends, Etc. can be done in one minute, I'm sure, except for the welding. I mention this to show how rapidly these could be made with the right set up. The dies can be made from mild steel plate, perhaps 1 inch thick, cut with a pattern torch, and then machined accurately with a CNC mill. The lower dies need to be accurately aligned.

Since the pressure to do this bending is really small the structure guiding the upper dies needs to be accurate but not exceptionally strong. I envision this set up to be made in sections that can be taken to the job site, accurately fastened together, and make the collectors there. They will be very light and bulky.

When the collectors are completed one method is to apply a thin coating of light grease to the inside. A thin plastic sheet with a good reflecting surface is then laid inside and smoothed onto the grease and rolled out smoothly, the grease holding it tightly by vacuum, and the top edges clamped to the lips of sheet 110 and 114. This allows easy replacement of the reflecting surface if it deteriorates or is damaged. This system makes an inexpensive but accurate parabolic collector. With the collectors mounted on an angle, the glass or plastic covering 94 would be somewhat self cleaning.

When I was designing this engine I thought about making the fire cylinder larger instead of making the fire piston smaller for the needed clearance between the two. On further consideration I saw that if the piston was full size its entire length, as it moved into the block cylinder it would be larger from its high temperature, and would jam in the colder cylinder. However if it did work from the cooling it continued to get from sliding in the block cylinder, its walls would be cooler and thereby cool the fire cylinder somewhat, thereby losing some of the heat in the combustion chamber and also some of its pressure.

Conclusion, Ramification And Scope

There are other ways to configure this engine. One is to use multiple (smaller) large cylinders, in place of the one, so the total volume would be the same. Another way is to use a longer piston travel with a smaller piston that would have an equal volume.

The large cylinder could receive the exhaust from a conventional engine. This would not have the advantage of the high temperature of the fire cylinder, but would give some extra free power.

There are also other possibilities, such as using all fire cylinders. This would lose efficiency but would be better than present engines.

Another is using multiple expansion cylinders as with the steam engine mentioned earlier. Any cylinder arrangement would work all right such as In Line, V, opposed, or other.

Thus the scope of this invention should be determined by the appended claims and their legal equivalents, rather than by the examples given.

### Materials

Super Alloys are one type of metal that look promising for this project. The book, ASM Metals Reference Book, Second Edition, Compiled by the American Society for Metals has lists of these. One list gives the strength of some of these at high temperatures. Some are based on nickel, and some on cobalt. Following are a few examples.

| | Temperature | Tensile strength | Yield strength |
|---|---|---|---|
| Name | deg. F. | ksi | ksi |
| Astroloy bar | 1600 | 112 | 100 |
| Udimet 700 bar | ″ | 100 | 92 |

ksi = 1000 pounds per square inch

These looked promising, but when I called the distributor, I found the first was no longer made, and the second was made only occasionally. I finally decided on HASTELLOY alloy X (HX). It is used in gas turbine combustion cans and other high temperature applications. It is not as strong as the first two, but has excellent forming and welding characteristics. It also has prolonged service temperatures of 1200 through 1600 Deg. F. for 16000 hours. I will use this in my prototype for the fire cylinder.

I bought it from HP alloys. 1-877-472-5569

There are other possibilities such as ceramics. Aluminum oxide Is used to insulate the electrode in spark plugs and operates at hi temperatures, with rapid pressure changes. Titanium nitride has a tensile strength of 60,000 psi at 4500 deg. F. to the best of my knowledge. I'm not acquainted with the workability of this. There are other materials that could be used, and each would need evaluating. The higher temperature the engine is operated at the greater its potential efficiency.

If a material, or a combination of materials is used to construct the fire cylinders, 36L&R and the upperlarge cylinders 36′ is made so it has insulation properties good enough to operate without the need for insulation 34L&R, and 34′ and/or cooling space 38L&R and 38′, this is equivalent to having fire cylinders with cooling spaces and/or insulation as above. This is also true with fire cylinders 36 and upper large cylinders 36B

14. An internal combustion compound reciprocating engine of the type operating according to the known four stroke cycle and comprising:
(a) primary cylinders and secondary cylinders arranged in groups of three with two said primary cylinders of equal size and a larger said secondary cylinders forming a group, preferably with said secondary cylinder between said primary cylinders, and as many of these groups can be incorporated in one engine as desired, said primary cylinders being distinguished from said secondary cylinder as serving as prime movers in a conventional manner, and initiating a combustion phase of the engines operating cycle as an expansion event;
(b) means including a reciprocal piston in each cylinder, a crankshaft, and connecting rods conventionally connecting the respective pistons to said crankshaft for converting the effects of fuel combustion into propulsive mechanical force as engine output; and cooling for the block cylinders,
(c) means for supplying primary air and fuel only to said primary cylinders, and in quantities for the most efficient use, and pollution control;
(d) means for timely igniting said air and fuel to effect engine working fluid;
(e) means including a head, and its intake and exhaust ports and their respective valves in said primary cylinders, and in said secondary cylinder; an exhaust port and its valve;
(f) gas transfer conduits, each compounding said primary cylinders and the adjacent said secondary cylinder, and particularly connecting said exhaust ports of each primary cylinder to a valveless port at and forming part of the combustion chamber of said secondary cylinder, whereby one said primary cylinder exhausts to said secondary cylinder on one revolution, and the other said primary cylinder exhausts to said secondary cylinder on the next revolution, together providing a power stroke for the secondary cylinder on every revolution, in a manner so each primary cylinder has a complete expansion cycle before exhausting into said secondary cylinder, and when that exhausting begins, the said secondary piston is at or near the top of its stroke, so it can have a complete cycle of expansion on each revolution without overlapping of their power strokes;
(g) means for opening and closing said valves in accordance with the timing required by the engine's operating cycle and regulated by said crankshaft;
(h) the cranks having crankpins disposed such that there is effected equal spacing of primary cylinder expansion events, equally spaced secondary cylinder expansion events, and said primary pistons in each group of three moving up and down together in a known manner, and the third, said secondary piston always moving in the opposite direction as said primary pistons;
(i) an exhaust system for transferring the engines final exhaust from said secondary cylinders to the atmosphere;
(j) wherein, the improvement comprises: added cylinders, of both primary type, called fire cylinders and secondary type called upper large cylinders, said fire cylinders, are placed on top of each block cylinder, extending toward said head, and of the same bore as said block cylinder below it and axially aligned with it and whose length is essentially the same as the stroke of the piston that moves in it,
(k) fire pistons slide in said block cylinders and are made as conventional pistons, with rings to seal the pressure from the combustion, and when each fire piston is at its top dead center, its top reaches to the top of said block cylinder as usual, with said rings still in said block cylinder, but above the top of said block, the piston continues up with a slightly smaller diameter, coaxial with its lower part, reaching up into said fire cylinder until its top is the right distance from said head to have the right compression ratio;
(l) said upper large cylinder is placed above the large block cylinder in the same manner as said fire cylinders, the large piston moving in said large block cylinder, with the same design as the fire piston and moves close enough to said head for a small amount of clearance, so they don't touch, its lower part sliding in said large block cylinder in a conventional manner, and including rings for sealing, with its upper part made smaller as in said fire cylinder;
(m) the space between said fire cylinder and said fire piston made by said smaller diameter of the top of said fire piston is only enough to prevent the two from touching each other in operation, the same is true of the space between said upper large cylinder and said large piston, and said cylinders and pistons of both types are made of material that can operate at high temperatures with adequate strength, said cylinders are cooled only if their temperature gets higher than the safe operating temperature of the material they are made from;
(n) whereby: the combustion and expansion takes place in a chamber surrounded by said fire cylinder, said fire piston and said head, said chamber not cooled, and its high temperature produces high pressures and it is isolated from the cooled block cylinder, which provides cooling, lubrication, sealing of pressure of said working fluid and guidance of the upper part of said piston; and with the secondary expansion performed in the same manner, it also operates hot, so the higher pressures in both said fire cylinders and said upper large cylinders, made from the high temperatures, make each produce more power for the amount of fuel consumed, and since no extra fuel is used in said upper large cylinder the combination makes a very efficient engine.

15. The engine of claim 14 further including: a supper charger to supply more air for greater power output, a cooling space and insulation around all said fire and said upper large cylinders, with means for minimum cooling of said block and said head by means of a small fan to save power, and an insulating gasket between said block and said head.

16. The engine of claim 15 further including: a material, or a combination of materials used to construct the fire cylinders, made so it has insulation properties good enough for operation without the need for insulation and/or cooling spaces around said cylinders, and this also includes the upper large cylinders.

17. The engine of claim 14 wherein said secondary cylinders instead of being one cylinder in each group of three, are multiple cylinders receiving the exhaust jointly and working together for its further expansion, said secondary cylinders may also have different strokes than said primary cylinders.

18. The engine of claim 15 wherein it operates as a two cycle engine of my design, but other compatible 2 cycle designs can also be used, said fire cylinders with means for firing and expanding on every revolution, their exhaust being delivered to said upper large cylinders which continue the expansion on every revolution, thus needing only one fire cylinder for each upper large cylinder which exhausts into the atmosphere on every revolution.

19. The engine of claim 15 further including the two cycle engine, with means for these engines to operate on a large variety of fuels.

20. The engine of claim 18 further providing, an air compressor unit to provide highly compressed air to the fire cylinder as needed for combustion, said air compressor being driven by the engine, and said compressed air with means of cooling between the compressor and the engine, means of insulation around said fire cylinders, and said upper large cylinders, with means for cooling said cylinders if overheated, means of cooling for the block and said head with means of said small fan to save power.

21. The engine of claim 19 further providing a hybrid electric drive for cars and trucks wherein lost energy from braking, and going up and down, hills is saved, to be used later.

22. The engine of claim 18 in which no internal combustion takes place, but the primary cylinder is an expander, delivering its exhaust to the secondary cylinder for full expansion or nearly so, or, alternately to a turbine, wherein heating of said working fluid is accomplished by means of external combustion.

23. means of a solar collector with means for following the sun, made of a parabolicly shaped trough to focus the suns rays on a pipe or its equivalent, to heat compressed cooled air to drive one of my engines, with means to connect a plurality of these said collectors together so they all follow the sun together, thus deriving energy without use of fuel.

24. The solar collector of claim 23 further including a means of reflectors located in a field surrounding a tower, top of said tower having means of a heat exchanger, said reflectors are controlled so each, continually, reflects the suns rays onto said heat exchanger to heat compressed cooled air to drive one or more of my engines and these controls can be adjusted to not follow the sun when needed.

25. In the operation of said internal combustion engines, air enters through intake valves, into said fire cylinders, is compressed, fuel is injected, and combustion takes place:
a. driving said fire pistons downward, and the high temperature, and high pressure of burning said working fluid encounters hot insulated fire cylinder walls and said fire pistons that are not cooled, and being very hot, they reflect the heat back into said working fluid to retain its heat, and thereby its pressure, and only losing heat by the work it is doing by expanding, driving the piston down;
b. thus delivering considerably more power for the same fuel input, and with hot said chamber walls there is less hydrocarbons emitted, and approaching the bottom of said fire piston's stroke, the exhaust valve opens, allowing said working fluid to exhaust and enter the upper large cylinder, which also operates hot, whose piston is now at the top of its stroke; and with less fuel used, less pollution will be generated;
c. and as said fire piston moves up, it pushes said working fluid through said exhaust valve, and the passage, and into the upper large cylinder thus mixing it more thoroughly, and allowing the unburned fuel that's left, to have a longer time to burn and;
d. the mixing allows the burning particles to find more oxygen for more complete burning, and the moving of said large piston downward with the pressure on its much larger cross sectional area causes a great deal of force on said crankshaft even though the pressure is falling;
e. and in operation, the temperature of said cylinders in any of these engines is expected to be up to red hot or higher, said working fluid is not cooled, as in a conventional engine with some of its energy and pressure lost to the radiator, but it retains essentially all of its pressure to expand and drive the piston down delivering more useful work with no more fuel;
f. the savings of fuel from the hot said fire cylinder, and said fire piston, combined with the free power from said upper large cylinder and large piston makes a very efficient engine, which by using less fuel means less pollution, and with large numbers of these engines in cars and trucks and other uses a great deal of fuel can be saved, as well as reducing pollution, and since this engine operates as conventional engines, except for certain additions and modifications, its reliability will be high;
g. and these engines with means of external combustion, will be useful in areas of high fuel costs and low wages and with waste biomass or other fuel used to make power, could be used for pumping water for irrigation, grinding grain, and other labor intensive tasks and;
h. with means of solar power, combined with my engine, which allows the complete expansion in hot cylinders, and having means of switching to fuel power automatically in the same engine, if the sun fails; in a partly cloudy day the switch from solar to fuel driven power could alternate back and forth as needed, and capture the available sun energy, and still supply a constant energy source, thereby saving fuel, and this is expected to be cost effective, and the manufacture of any of these engines is like any internal combustion engine with some added parts, and modifications so its development will not be difficult.
